(19) United States
(12) Patent Application Publication
(10) Pub. No.: US 2006/0151826 A1
(43) Pub. Date: Jul. 13, 2006

(54) Semiconductor device having a barrier layer and method of manufacturing the same

(76) Inventors: Beom-Jun Jin, Seoul (KR); Hong-Bae Park, Seoul (KR); Seong-Geon Park, Yonginsi (KR); Yu-Gyun Shin, Seongnam-si (KR); Sang-Bom Kang, Seoul (KR)

Correspondence Address: HARNESS, DICKEY & PIERCE, P.L.C., P.O. BOX 8910, RESTON, VA, 20195, US

(21) Appl. No.: 11/326,286

(22) Filed: Jan. 6, 2006

(30) Foreign Application Priority Data
Jan. 7, 2005 (KR) 2005-1494

(51) Int. Cl. H01L 29/788

(52) U.S. Cl. 257/316

(57) ABSTRACT

A semiconductor device may include a gate structure having a gate insulation layer formed on a substrate, and a gate electrode formed on the gate insulation layer. A composite barrier layer may be formed on the gate structure.

### PRIORITY CLAIM

A claim of priority is made under 35 U.S.C. § 119 to Korean Patent Application No. 2005-1494, filed on Jan. 7, 2005, the contents of which are herein incorporated by reference in their entirety.

### BACKGROUND OF THE INVENTION

1. Field of the Invention

Example embodiments of the present invention generally relate to a semiconductor device having a barrier layer and a method of manufacturing the semiconductor device. More particularly, example embodiments of the present invention relate to a semiconductor device having a barrier layer that may be capable of reducing diffusion of oxidizing agents and/or reducing or preventing a punch-through effect, and a method of manufacturing the semiconductor device.

2. Description of the Related Art

In general, several processes may be carried out on a semiconductor substrate to manufacture a semiconductor device. For example, a deposition process may be performed to form a layer on the semiconductor substrate. An oxidation process may be carried out to form an oxide layer on the semiconductor substrate or to oxidize a layer on the semiconductor substrate. A photolithography process may be performed to convert a layer on the semiconductor substrate into a pattern. Furthermore, a planarization process may be carried out to planarize a layer on the semiconductor substrate.

A semiconductor device may include volatile memory devices, for example, a dynamic random access memory (DRAM), a static random access memory (SRAM), and non-volatile memory devices, for example, an electrically erasable and a programmable read only memory (EEPROM), and a flash memory.

The semiconductor device may include a gate structure having a gate insulation layer or a tunnel oxide layer. The gate structure may be formed by a deposition process and/or a photolithography process.

A field effect transistor of a DRAM may include a gate structure having a gate insulation layer, a gate electrode, and/or impurity regions formed adjacent to the gate structure on surface portions of a semiconductor substrate. A flash memory device may include a gate structure having a tunnel oxide layer, a floating gate electrode, a gate dielectric layer, a control gate electrode, and/or impurity regions formed adjacent to the gate structure on surface portions of a semiconductor substrate.

In a method of forming a gate structure of a field effect transistor, a gate insulation layer may be formed on a semiconductor substrate. A polysilicon layer doped with impurities may be formed on the gate insulation layer. The polysilicon layer and the gate insulation layer may be anisotropically etched to complete the gate structure.

During the anisotropic etching process using plasma ion energy to form the gate structure, impact of the ions may damage the semiconductor substrate and the gate structure. Specifically, a leakage current between the gate electrode and the semiconductor substrate may increase due to a damaged gate insulation layer. The increase in leakage current may deteriorate refresh characteristics of a DRAM device.

To cure ion impact damage, the semiconductor substrate and the gate structure may be re-oxidized. The re-oxidation process may be carried out in a furnace type apparatus at a temperature of about 700° C. to about 900° C. using O₂, O₃, and/or H₂O.

If the gate insulation layer includes a silicon oxide layer, an oxidizing agent may diffuse into an edge of a silicon oxide layer during a re-oxidation process, which may generate a bird's beak at an edge of the silicon oxide layer. The oxidizing agent may further diffuse into a central portion of the silicon oxide layer to increase the thickness of the silicon oxide layer.

Further, if the gate insulation layer is formed of a material having a high dielectric constant, silicon oxide layers may be formed at interfaces between the semiconductor substrate and the gate insulation layer, and between the gate insulation layer and the gate electrode due to the diffusion of the oxidizing agent. Examples of a high dielectric constant layer may include HfO₂, HfAlO, HfSixOy, HfSixOyNz, ZrO₂, ZrSixOy, ZrSixOyNz, Al₂O₃, TiO₂, Y₂O₃, Ta₂O₅, Nb₂O₅, BaTiO₃, SrTiO₃, or a combination thereof.

A threshold voltage and an equivalent oxide layer thickness (EOT) may increase due to the silicon oxide layers. As a result, transistors in a cell region or a peripheral region may have poor operational capacity.

### SUMMARY OF THE INVENTION

Example embodiments of the present invention provide a semiconductor device having a barrier layer that is capable of suppressing, for example reducing or eliminating, diffusion of an oxidizing agent.

In an example embodiment of the present invention a semiconductor device may include a gate structure having a gate insulation layer and a gate electrode formed on a substrate. The semiconductor device may further include a barrier layer formed on the gate structure.

In an example embodiment of the present invention, a method of manufacturing a semiconductor device may include forming a gate structure on a substrate, the gate structure may include a gate insulation layer and a gate electrode, and forming a barrier layer on the gate structure.

### BRIEF DESCRIPTION OF THE DRAWINGS

Example embodiments of the present invention will become readily apparent with the reference to the following detailed description when considered in conjunction with the accompanying drawings wherein:

FIGS. 1 to 4 are cross sectional views illustrating a method of manufacturing a semiconductor device in accordance with an example embodiment of the present invention; and

FIG. 5 is a graph illustrating threshold voltages for the semiconductor device of FIG. 4 and conventional semiconductor devices.

### DESCRIPTION OF EXAMPLE EMBODIMENTS OF THE PRESENT INVENTION

The present invention will be described in more detail with reference to the accompanying drawings, in which example embodiments of the present invention are illustrated. The present invention may, however, be embodied in many different forms and should not be construed as limited to the example embodiments set forth herein. Rather, these example embodiments are provided as working example. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

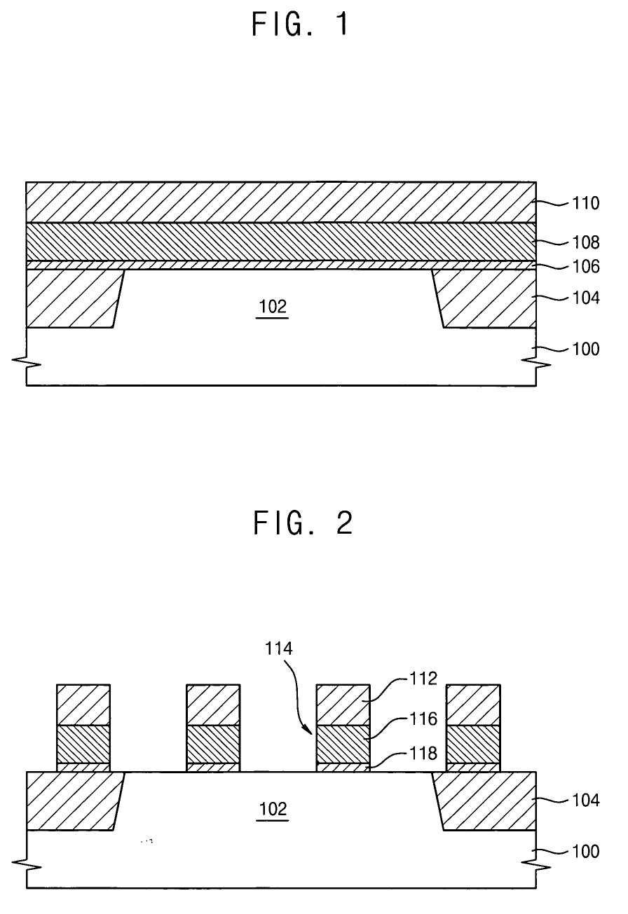

FIGS. 1 to 4 are cross sectional views illustrating a method of manufacturing a semiconductor device in accordance with an example embodiment of the present invention.

Referring to FIG. 1, a semiconductor substrate 100, for example, silicon may be divided into an active region and a field region by an isolation process. In particular, isolation layers 104 and an active pattern 102 may be formed on the semiconductor substrate 100 by a local oxidation of silicon (LOCOS) process or a shallow trench isolation (STI).

A preliminary gate insulation layer 106 may be formed on the semiconductor substrate 100. Example materials of the preliminary gate insulation layer 106 may include a silicon oxide layer and a high dielectric constant layer. Examples of a high dielectric constant layer may include HfO₂, HfAlO, HfSixOy, HfSixOyNz, ZrO₂, ZrSixOy, ZrSixOyNz, Al₂O₃, TiO₂, Y₂O₃, Ta₂O₅, Nb₂O₅, BaTiO₃, SrTiO₃, or a combination thereof. Furthermore, the high dielectric constant layer may be formed by a thermal chemical vapor deposition (CVD) process, a plasma enhanced chemical vapor deposition (PECVD) process, a physical vapor deposition (PVD) process, or an atomic layer deposition (ALD) process.

In particular, a silicon oxide layer may be formed by a rapid thermal oxidation process, a furnace thermal oxidation process, or a plasma oxidation process. For example, the semiconductor substrate 100 may be heated to a temperature of about 800° C. to about 950° C. A reaction gas including oxygen may be applied to the semiconductor substrate 100 to form the silicon oxide layer. In addition, the silicon oxide may be nitrified to form a silicon oxynitride (SiON) layer.

For example, a source gas containing hafnium and an oxidation gas containing oxygen may be applied to the semiconductor substrate 100 to form an HfO₂ layer on the semiconductor substrate 100. Examples of the source gas may include Hf[N(CH₃)₂]₄ (tetrakis dimethyl amino hafnium; TDMAH), Hf[N(C₂H₅)CH₃]₄ (tetrakis ethyl methyl amino hafnium; TEMAH), Hf[N(C₂H₅)₂]₄ (tetrakis diethyl amino hafnium; TDEAH), hafnium buthyloxide (Hf(O-tBu)₄), or a combination thereof. Examples of the oxidation gas may include O₃, O₂, H₂O, or a combination thereof.

Alternatively, a first source gas containing hafnium, a second source gas containing silicon, and an oxidation gas may be applied to the semiconductor substrate 100 to form a hafnium oxide layer containing silicon (HfSiₓO_{y}). An example of the second source gas may include silane (SiH₄). Additionally, the hafnium oxide layer containing silicon may be nitrified to form a hafnium oxynitride layer containing silicon (HfSiₓO_{y}N_{z}).

A conductive layer 108 may be formed on the preliminary gate insulation layer 106. In particular, a polysilicon layer doped with impurities may be formed on the preliminary gate insulation layer 106. The polysilicon layer may be formed by a low pressure chemical vapor deposition (LPCVD) process using a silicon source gas for example silane. Further, the polysilicon layer may be doped with impurities by an impurity diffusion process, an ion implantation process, or an in-situ doping process.

A metal silicide layer (not shown) may be formed on the polysilicon layer. Examples of the metal silicide layer may include a tungsten silicide (WSiₓ) layer, a titanium silicide (TiSiₓ) layer, a cobalt silicide (CoSiₓ) layer, a tantalum silicide (TaSix) layer, or a combination thereof. Alternatively, a metal layer, for example, a tungsten layer may be formed on the polysilicon layer doped with impurities.

A mask layer 110 may be formed on the conductive layer 108. The mask layer 110 may include a silicon nitride layer. The mask layer 110 may be formed by an LPCVD process or a PECVD process using a silicon source gas containing SiH₂Cl₂ or SiH₄ and a nitridation gas containing NH₃.

Referring to FIG. 2, a photoresist pattern (not shown) may be formed on the mask layer 110 by a photolithography process. The mask layer 110 may be anisotropically etched using the photoresist pattern as an etching mask to form a mask pattern 112. The conductive layer 108 and the preliminary gate insulation layer 106 may be anisotropically etched using the mask pattern 112 as an etching mask to form a gate structure 114 and a gate insulation layer 118 on the semiconductor substrate 100.

In particular, the conductive layer 108 and the preliminary gate insulation layer 106 may be partially removed by the anisotropic etching process using plasma ion energy to form the gate structure 114 including a gate electrode 116 and the gate insulation layer 118.

In an example embodiment, the gate electrode 116 may include polysilicon. Alternatively, the gate electrode 116 may include a polysilicon layer pattern and a metal silicide layer pattern or a metal pattern formed on the polysilicon layer pattern.

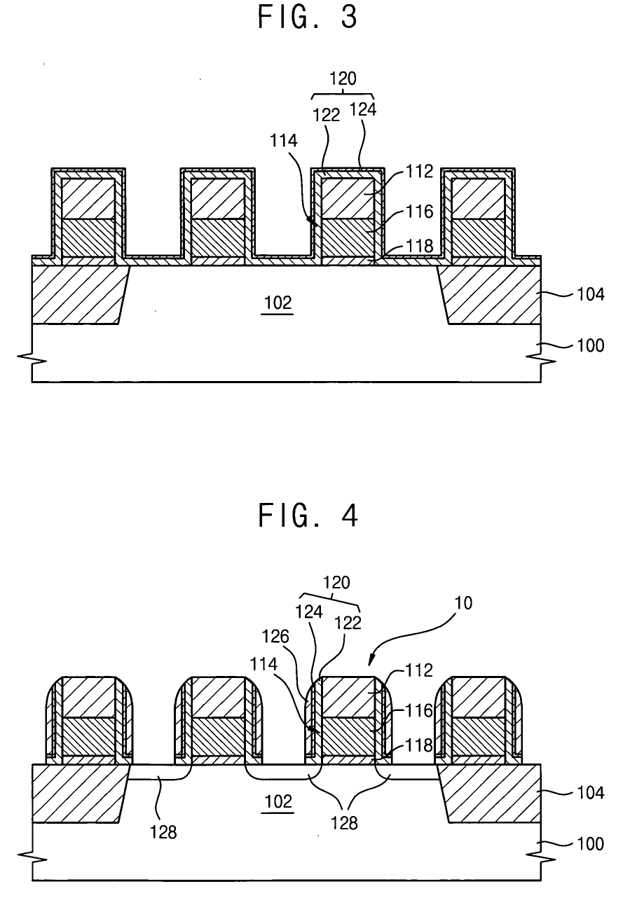

Referring to FIG. 3, a barrier layer 120 may include an oxide layer and an oxynitride layer, which may be formed on the gate structure 114. The barrier layer 120 may suppress, for example reduce or eliminate, an oxidizing agent from diffusing in a subsequent thermal treatment process. The barrier layer 120 may be a single layer, single oxide layer, a composite layer, or a composite layer of least one oxide layer and at least one oxynitride layer.

For example, the oxide layer may be formed on the gate structure 114 by a thermal CVD process. For example, a silicon source gas containing SiH₂Cl₂ or SiH₄ and an oxidation gas containing N₂O may be applied to the semiconductor substrate 100 at a temperature of about 700° C. to about 900° C. under a pressure of about 0.1 Torr to about 10 Torr by an LPCVD process or a thermal CVD process to form a silicon oxide layer 122 having a thickness of about 10 521 to about 100 Å.

A surface of the silicon oxide layer 122 may be further nitrified to form a silicon oxynitride layer 124. The silicon oxynitride layer 124 may be formed by a plasma nitridation process or a thermal nitridation process.

The plasma nitridation process may be carried out using nitrogen plasma containing nitrogen radicals. For example, the plasma nitridation process may be performed using a nitridation gas containing N₂, NH₃, NO, or N₂O, and a carrier gas containing Ar or He, at a temperature of about 600° C. under a pressure of about 1 mTorr to about 10 Torr. Further, the plasma nitridation process may be carried out using remote plasma that may be generated from a remote plasma generator connected to a process chamber or direct plasma that may be generated in the process chamber. For example, a remote plasma generator using a microwave energy source, a radio frequency (RF) power source or a modified magnetron type (MMT) plasma generator may be used for the plasma nitridation process.

A thermal nitridation process may be carried out using a nitridation gas containing N₂, NH₃, NO, or N₂O at a temperature of about 700° C. to about 950° C. under a pressure of about 1 mTorr to about 10 Torr.

The silicon oxynitride layer 124 may be formed to a thickness of about 0.1 to about 0.3 times that of the silicon oxide layer 122, for example, about 0.15 to about 0.2 times that of the silicon oxide layer 122.

Alternatively, the barrier layer 120 may be formed by a PECVD process. For example, the silicon oxide layer 122 may be formed on the gate structure 114 by a PECVD process using SiH₄ gas and O₂ gas or N₂O gas. NH₃ gas may be then applied to the silicon oxide layer 122 to form the silicon oxynitride layer 124. The silicon oxide layer 122 and the silicon oxynitride layer 124 may be formed in-situ.

Thermal energy generated during the formation of the barrier layer 120 may partially cure damages of the semiconductor substrate 100 and the gate structure 114 caused by plasma used to form the gate structure 114. However, damage on the semiconductor substrate 100 and the gate structure 114 may not be completely cured, therefore, leakage current through the gate insulation layer 118 may be still generated. Thus, an additional thermal treatment with respect to the semiconductor substrate 100 having the gate structure 114 may be performed.

To further cure the damage of the semiconductor substrate 100 and the gate structure 114, the thermal treatment may be carried out for about several seconds to about several hours. For example, when a rapid thermal apparatus is used for the thermal treatment, the thermal treatment may be performed for about several seconds to about tens of seconds. When a furnace type apparatus is used for the thermal treatment, the thermal treatment may be carried out for about 5 minutes to about several hours.

Further, the thermal treatment may be carried out under an oxidation gas atmosphere containing O₂, O₃, or H₂O at a temperature of about 500° C. to about 1,000° C., for example about 700° C. to about 950° C., for example about 850° C. under a pressure of about 1 mTorr to about 10 Torr. Alternatively, the thermal treatment may be carried out under an oxygen plasma atmosphere and/or a hydrogen plasma atmosphere.

During the thermal treatment, an oxidizing agent, for example, oxygen radicals or hydroxide radicals may be generated in the thermal treatment apparatus. However, the barrier layer 120 on the gate structure 114 may suppress, for example reduce or eliminate, the oxidizing agent from diffusing into interfaces between the semiconductor substrate 100 and the gate insulation layer 118, and between the gate insulation layer 118 and the gate electrode 116. Thus, a thickness of the gate insulation layer 118 may not increase. Also, additional silicon oxide layers may not be formed.

Referring to FIG. 4, after the completion of the thermal treatment, spacers 126 may be formed on sidewalls of the barrier layer 120. For example, a silicon nitride layer may be formed on the barrier layer 120. The silicon nitride layer may be anisotropically etched to form the spacers 126. Impurities may be implanted into portions of the semiconductor substrate 100 adjacent to the gate structure 114 to form impurity regions 128 corresponding to source/drain regions to thereby complete the formation of a transistor 10.

Each impurity region 128 further may include a lightly doped impurity region (not shown) and a heavily doped impurity region (not shown). First impurities may be implanted into the semiconductor substrate 100 prior to the formation of the spacers 126 to form the lightly doped impurity region. Also, second impurities may be implanted into the semiconductor substrate 100 after the formation the spacers 126 to form the heavily doped impurity region.

The barrier layer 120 may serve as a pad oxide layer to protect the surface of the semiconductor substrate 100 during a first ion implantation process. Additionally, prior to a second ion implantation process, a second pad oxide layer (not shown) may be formed on the spacers 126 to protect exposed surfaces of the semiconductor substrate 100.

According to example embodiments of the present embodiment, the barrier layer 120 on the gate structure 114 may suppress, for example reduce or eliminate, diffusion of an oxidizing agent to control a thickness of the gate insulation layer 118 and/or the formation of additional silicon oxide layer. Therefore, a threshold voltage of the semiconductor device and an EOT of the gate insulation layer 118 may be suppressed.

A gate structure as described in FIGS. 1-4 may be formed on a semiconductor substrate. The gate structure may include a gate insulation layer including silicon containing hafnium oxynitride on a semiconductor substrate. A barrier layer having a thickness of 15 Å may be formed on the gate structure. A silicon oxide layer of the barrier layer may be formed by a thermal CVD process using SiH₂Cl₂ gas and N₂O gas at a temperature of about 850° C. Further, a silicon oxynitride layer of the barrier layer may be formed by a plasma nitridation process using nitrogen plasma. A semiconductor substrate having the gate structure and the barrier layer may be thermally treated in a furnace type apparatus at a temperature of about 850° C. for about 30 minutes.

### COMPARATIVE EXAMPLE 1

A transistor without a barrier layer and not thermally treated was manufactured to be used as a Comparative Example 1.

### COMPARATIVE EXAMPLE 2

A transistor without a barrier layer but thermally treated was manufactured to be used as a Comparative Example 2.

Measuring Threshold Voltages of the Transistors

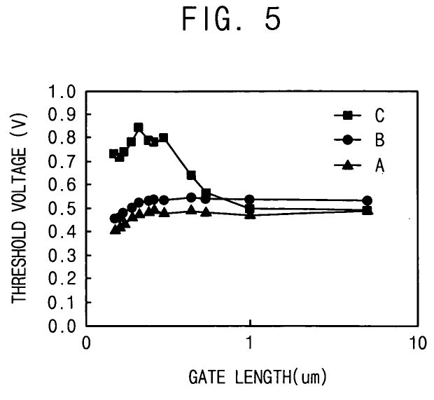

Threshold voltages of the example transistor of FIG. 4, and the transistors of Comparative Examples 1 and 2 were measured. The measured threshold voltages are illustrated in FIG. 5. In FIG. 5, a horizontal axis represents a length of a gate, and a vertical axis represents a threshold voltage. Line A represents the threshold voltage of the transistor of FIG. 4, line B represents the threshold voltage of the transistor in Comparative Example 1, and line C represents the threshold voltage of the transistor in Comparative Example 2.

As illustrated in FIG. 5, the example transistor of FIG. 4 has a threshold voltage substantially similar to that of the transistor in Comparative Example 1, but much lower than that of the transistor in Comparative Example 2. The threshold voltage of the example transistor of FIG. 4 is relatively constant regardless of its gate length. On the contrary, the threshold voltage of the transistor in Comparative Example 2 increased proportionally to a decrease in its gate length. Therefore, in the transistor of Comparative Example 2, an oxidizing agent diffused during a thermal treatment to form silicon oxide layers, which caused an increase of the threshold voltage, between a semiconductor substrate and a gate insulation layer, and between a gate insulation layer and a gate electrode. Therefore, the transistor of Comparative Example 2 displays deteriorated operational characteristics due to the increased threshold voltage.

Although the transistor in Comparative Example 1 had a threshold voltage substantially similar to that of the example transistor in FIG. 4, etching damage on the semiconductor substrate and the gate structure were not cured, because the transistor in Comparative Example 1 was not manufactured with a thermal treatment. Thus, a large amount of leakage current through the gate insulation layer of the transistor in Comparative Example 1 may be generated, thereby decreasing operational characteristics.

According to example embodiments of the present invention, a barrier layer on a gate structure may suppress an oxidizing agent from diffusing into interfaces between a semiconductor substrate and a gate insulation layer and/or between a gate insulation layer and a gate electrode to control a thickness of the gate insulation. Also, additional silicon oxide layers may not be formed. As a result, a threshold voltage of the semiconductor device may be decreased. Further, an EOT of the gate insulation layer may not be increased. Thus, the semiconductor device may have improved operational characteristics.

Having described the example embodiments of the present invention, it is noted that modifications and variations can be made by persons skilled in the art in light of the above teachings. It is therefore to be understood that changes may be made in the example embodiment of the present invention disclosed which is within the scope of the example embodiments of the present invention.

What is claimed is:

1. A semiconductor device, comprising:
a gate structure including a gate insulation layer and a gate electrode formed on a substrate; and
a barrier layer formed on the gate structure, the barrier layer suppressing materials from diffusing into interfaces between the substrate and gate insulation layer, and between the gate insulation layer and the gate electrode.

2. The semiconductor device of claim 1, wherein the barrier layer includes an oxide layer.

3. The semiconductor device of claim 1, wherein the barrier layer is a composite barrier layer including:
at least one oxide layer formed on the gate structure; and
at least one oxynitride layer formed on the at least one oxide layer.

4. The semiconductor device of claim 3, wherein the barrier layer is composite barrier layer including:
at least one silicon oxide layer formed on the gate structure; and
at least one silicon oxynitride layer formed on the at least one silicon oxide layer.

5. The semiconductor device of claim 1, wherein the gate insulation layer is formed from a material including silicon oxide, silicon oxynitride and a combination thereof.

6. The semiconductor of claim 5, wherein the gate insulation layer is formed of HfO₂, HfAlO, HfSiₓO_{y}, HfSiₓO_{y}N_{z}, ZrO₂, ZrSiₓO_{y}, ZrSiₓO_{y}N_{z}, Al₂O_{3, TiO}₂, Y₂O₃, Ta₂O₅, Nb₂O₅, BaTiO₃, SrTiO₃, and a combination thereof.

7. The semiconductor device of claim 1, wherein the gate electrode includes a polysilicon layer pattern doped with impurities.

8. The semiconductor device of claim 1, further comprising spacers formed on the barrier layer, and impurity regions formed on the substrate adjacent to the gate structure.

9. The semiconductor device of claim 1, wherein the barrier layer is a composite barrier layer of an oxide layer and an oxynitride layer formed on the gate structure.

10. A method of manufacturing a semiconductor device, comprising:
forming a gate structure on a substrate, the gate structure including a gate insulation layer and a gate electrode; and
forming a barrier layer on the gate structure, the barrier layer to reduce materials from diffusing into interfaces between the substrate and gate insulation layer, and between the gate insulation layer and the gate electrode.

11. The method of claim 10, further including thermally treating the substrate after the formation of the barrier layer.

12. The method of claim 10, wherein forming the barrier layer includes:
forming at least one an oxide layer on the gate structure; and
nitrifying a surface of the at least one oxide layer to form at least one oxynitride layer.

13. The method of claim 10, wherein forming the barrier layer includes:
forming at least one silicon oxide layer on the gate structure; and
nitrifying a surface of the at least one silicon oxide layer to form at least one silicon oxynitride layer.

14. The method of claim 13, wherein a thickness of the at least one silicon oxynitride layer is about 0.1 to 0.3 times that of a thickness of the at least one silicon oxide layer.

15. The method of claim 13, wherein forming the at least one silicon oxide layer includes at least one of a thermal chemical vapor deposition (CVD) process and a low pressure chemical vapor deposition (LPCVD) process.

16. The method of claim 15, wherein the CVD process includes providing a silicon source gas containing SiH₂Cl₂ or SiH₄ and an oxidation gas containing N₂O to the semiconductor substrate at a temperature of about 700° C. to about 900° C. under a pressure of about 0.1 Torr to about 10 Torr.

17. The method of claim 13, wherein forming the at least one silicon oxynitride layer includes at least one of a plasma nitridation process and a thermal nitridation process.

18. The method of claim 17, wherein the plasma nitridation process includes providing a nitridation gas containing N₂, NH₃, NO, N₂O, or a combination thereof and a carrier gas containing Ar, He or a combination thereof at a temperature of about 600° C. under a pressure of about 1 mTorr to about 10 Torr.

19. The method of claim 17, wherein the thermal nitridation process includes providing a nitridation gas containing N₂, NH₃, NO, N₂O, or a combination thereof and a carrier gas containing Ar, He or a combination thereof at a temperature of about 700° C. to 950° C. under a pressure of about 1 mTorr to about 10 Torr.

20. The method of claim 13, wherein forming the at least one silicon oxide layer and the at least one silicon oxynitride layer includes a plasma enhanced chemical vapor deposition (PECVD) process.

21. The method of claim 11, wherein thermally treating the substrate is performed under an atmosphere including O₂, O₃, H₂O or a combination thereof.

22. The method of claim 11, wherein thermally treating the substrate is performed under at least one of an oxygen plasma and a hydrogen plasma atmosphere.

23. The method of claim 11, wherein thermally treating the substrate is carried out at a temperature of about 500° C. to about 1,000° C.

24. The method of claim 23, wherein thermally treating the substrate is carried out at a temperature of about 700° C. to about 950° C.

25. The method of claim 10, wherein forming the gate structure including:
forming an isolation layer and an active pattern in the substrate;
forming a preliminary gate insulation layer on the substrate;
forming a conductive layer on the preliminary gate insulation layer; and
anisotropically etching the preliminary gate insulation layer and the conductive layer to form the gate insulation layer and the gate electrode.

26. The method of claim 10, further including:
forming spacers on the barrier layer; and
forming impurity regions on the substrate adjacent to the gate structure.
